(19) United States
(12) Patent Application Publication
(10) Pub. No.: US 2023/0104095 A1
(43) Pub. Date: Apr. 6, 2023

(54) TESTING DEVICE AND METHOD FOR TESTING DEVICES UNDER TEST

(71) Applicant: NANYA TECHNOLOGY CORPORATION, New Taipei City (TW)

(72) Inventors: Chun-Ying LAI, New Taipei City (TW); Hung-An TAI, Taoyuan City (TW); Chih-Ming CHANG, Taoyuan City (TW)

(21) Appl. No.: 17/449,814

(22) Filed: Oct. 4, 2021

(51) Int. Cl. G01R 1/04

(52) U.S. Cl. CPC G01R 1/0416

(57) ABSTRACT

A testing device includes a power supply and a plurality of testing ports. The testing ports are electrically connected to the power supply. Each of the testing ports includes a contact and a current clamper. The contact is configured to electrically couple a device under test (DUT). The current clamper is connected between the power supply and the contact and configured to allow a limited current having a predetermined current value to flow to the contact.

### BACKGROUND

### Field of Invention

The present invention relates to a testing device and a method for testing devices under test (DUTs).

### Description of Related Art

The current method to provide power for DUTs is mainly through connecting the DUTs in parallel and jointly connecting them to a power supply. Therefore, the current value of each DUT will be controlled by the total number of the DUTs and the total current value of the power supply. In general, the total current value of the power supply is fixed, and when the number of the DUTs is different, the current will change correspondingly. If the current value does not meet the operation requirement of the DUT, there might cause the increment of its measurement error and the reduction of the efficiency.

### SUMMARY

An aspect of the present disclosure is related to a testing device and method of testing thereof.

According to an embodiment of the present disclosure, a testing device includes a power supply and a plurality of testing ports. The testing ports are electrically connected to the power supply. Each of the testing ports includes a contact and a current clamper. The contact is configured to electrically couple a device under test (DUT). The current clamper is connected between the power supply and the contact and configured to allow a limited current having a predetermined current value to flow to the contact.

In an embodiment of the present disclosure, the testing ports are connected in parallel.

In an embodiment of the present disclosure, the current clamper is configured to allow the limited current to flow to the contact when a current from the power supply to the current clamper is equal to or greater than the limited current.

In an embodiment of the present disclosure, the current clamper is configured to not allow the limited current to flow to the contact when a current from the power supply to the current clamper is smaller than the limited current.

In an embodiment of the present disclosure, each of the testing ports further includes a switch connected between the power supply and the current clamper.

In an embodiment of the present disclosure, the power supply is configured to provide a constant current, and a sum of the limited currents respectively flowing through the current clampers is equal to or smaller than the constant current.

According to an embodiment of the present disclosure, a method for testing a plurality of DUTs is provided. The method includes: electrically coupling a plurality of testing ports to the DUTs respectively; supplying a constant current to the testing ports; and making each of the testing ports to allow a limited current having a predetermined current value to flow to a corresponding one of the DUTs.

In an embodiment of the present disclosure, a sum of the limited currents respectively flowing through the testing ports is equal to or smaller than the constant current.

In an embodiment of the present disclosure, the method further includes making electrical disconnection inside at least one of the testing ports when at least one of the DUTs corresponding thereto is determined to be failed.

In an embodiment of the present disclosure, a sum of the limited currents respectively flowing through rest of the testing ports is smaller than the constant current.

In the aforementioned embodiments of the present disclosure, the current clamper can achieve the purpose of maintaining the operating efficiency of the production line while controlling the current value, because the current clamper in the testing port can automatically control the value of the current inputted into the DUT. Therefore, the purpose of maintaining the operating efficiency of the production line while controlling the current value can be achieved. The current clampers can control the input current to each DUTs, so the current with a current value smaller than the limited current value can be prevented from being inputted into the DUT. Also the current clampers can avoid causing measurement errors or affecting measurement efficiency due to unstable current when the DUT is under operation. The current clamper can output an output current with a value equal to the limited current value to the DUT, so as to protect the DUT to avoid overloading the circuit of the DUT due to excessive input current. The switch of each of the testing ports can selectively form a path or an open circuit between a corresponding DUT and the power supply, so that the DUT of the production line can perform maintenance or overhaul.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a schematic diagram of a testing device according to one embodiment of the present disclosure;

FIG. 2 illustrates another schematic diagram of the testing device shown in FIG. 1; and

FIG. 3 illustrates a flow chart of a method for testing a plurality of DUTs according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “front,” “back” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

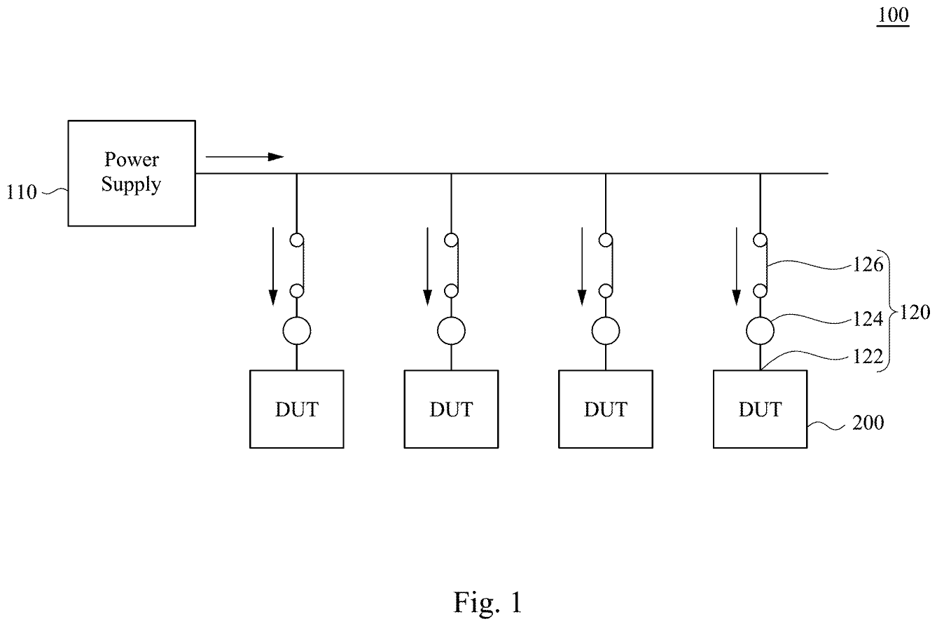

Reference is made to FIG. 1. FIG. 1 illustrates a schematic diagram of a testing device 100 according to one embodiment of the present disclosure. As shown FIG. 1, a testing device 100 includes a power supply 110 and a plurality of testing ports 120. The testing ports 120 are electrically connected to the power supply 110. Each of the testing ports 120 includes a contact 122 and a current clamper 124. The contact 122 is configured to electrically couple a DUT 200. The current clamper 124 is connected between the power supply 110 and the contact 122 and configured to allow a limited current having a predetermined current value to flow to the contact 122. The testing device 100 can be combined with automatic manufacturing equipment (for example, a production line), but the present disclosure is not limited to this.

In the embodiment shown in FIG. 1, the number of the DUTs 200 is four, but the disclosure is not limited to this. Specifically, the number of the DUTs 200 can be any value, and the DUTs 200 can be replaced with other devices that can be powered by the power supply 110. In the embodiment of the present disclosure, the testing ports 120 are connected in parallel, but the disclosure is not limited to this. Different electrical connections between the DUTs 200 and the power supply 110 will affect the current allocated to each DUT 200. For example, the current value distributed by the power supply 110 to each DUT 200 is equal when the DUTs 200 are connected to the power supply 110 in parallel.

In some embodiments, the testing device 100 may provide at least one current clamper 124 between the contact 122 and the DUT 200, but the disclosure is not limited to this. In some embodiments, the current clamper 124 is configured to allow the limited current to flow to the contact 122 when a current flows from the power supply 110 to the current clamper 124 is equal to or greater than the limited current. In some other embodiments, the current clamper 124 is configured to not allow the current to flow to the contact 122 when a current from the power supply 110 to the current clamper 124 has a current value smaller than the limited current value. Specifically, the current clamper 124 can set a limited current value, and when it is electrically connected between the power supply 110 and a corresponding one of the DUTs 200, the value of the current passing through the current clamper 124 is limited according to the limited current value. The function of the current clamper 124 is to prevent the current with a current value that is smaller than the limited current value from being inputted into the DUT 200, so as to avoid causing measurement errors or affecting measurement efficiency due to unstable current when the DUT 200 is under operation. For example, the limited current value of the current clamper 124 is about 200 mA. With the filtering of the current clamper 124, only the input current greater than or equal to about 200 mA can pass through the current clamper 124. If the input current is less than about 200 mA, the testing port 120 will form an open circuit between the power supply and the DUT 200.

In some embodiments, each of the testing ports 120 further includes a switch 126 connected between the power supply 110 and the current clamper 124, but the present disclosure is not limited to this. For example, the switch 126 can also be placed in other positions of the circuit or combined with a current clamper 124. The purpose of connecting the switch 126 between the power supply 110 and the current clamper 124 is mainly to selectively form a path or an open circuit between the power supply 110 and a corresponding one of the DUTs 200, so that the DUTs 200 of the production line can perform maintenance or overhaul. In some embodiments, the power supply 110 is configured to provide a constant current, and a sum of the limited currents respectively flowing through the current clampers 124 is equal to or smaller than the constant current, but the present disclosure is not limited to this. Specifically, the total current provided by the power supply 110 must provide the sum of the current required by all DUTs to ensure that the DUTs 200 can operate with its maximum efficiency.

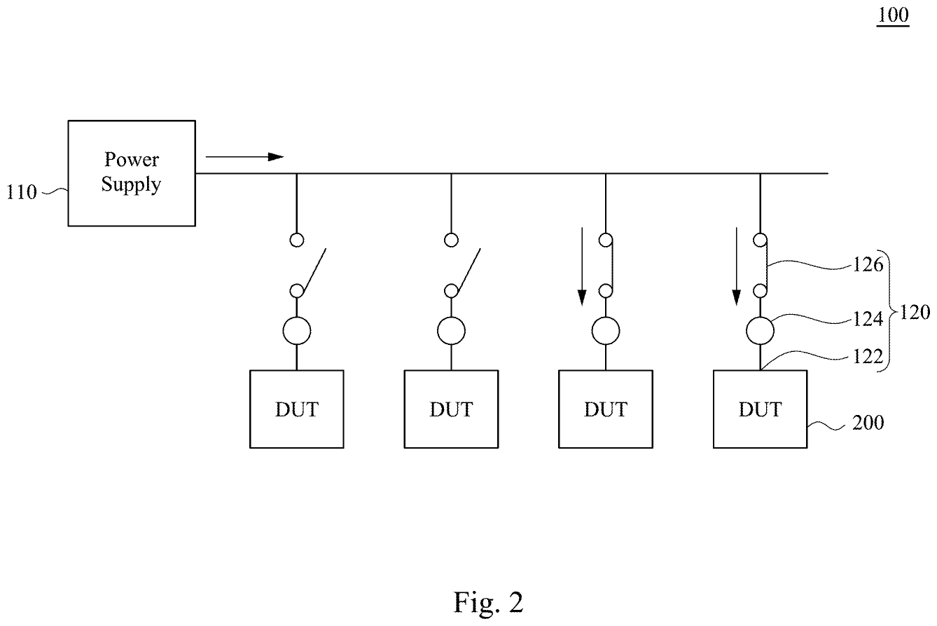

Reference is made to FIG. 2. FIG. 2 illustrates another schematic diagram of the testing device shown in FIG. 1. The following will be described with specific examples in combination with the above various embodiments and with reference to FIG. 1 and FIG. 2. As shown in FIG. 1, the power supply 110 is connected to four DUTs 200. Assuming that the input current obtained by each DUT 200 is about 200 mA, and the total current output by the power supply 110 is about 800 mA. As shown in FIG. 2, the switches 126 of two of the testing ports 120 are turned off to form open circuits, and the other two testing ports 120 are still electrically connected to the power supply 110 at this time. If there is no current clamper 124 connected between the DUT 200 and the contact 122, the total current of 800 mA of the power supply 110 will be divided equally to the two DUTs 200 owing to the configuration of the series circuit. In other words, each of the two DUTs 200 receives about 400 mA individually. However, the current of 400 mA is greater than the rated input current value of the DUT 200, which will cause the DUTs 200 to overload. Generally speaking, the input current of each DUT 200 can be indirectly adjusted by changing the total current value that provided by the power supply 110. However, the current value must be manually calculated and adjusted, which will reduce the work efficiency of the production line. The current clamper 124 in the testing port 120 can control the value of the input current of the DUT 200. The current clamper 124 can achieve the purpose of maintaining the operating efficiency of the production line while controlling the current value. As shown in FIG. 2, the current clampers 124 are connected to the DUTs 200 respectively. In this way, with the current limiting effect of the current clamper 124, the value of the input current to each DUTs 200 can be maintained without adjusting the total output current value of the power supply 110.

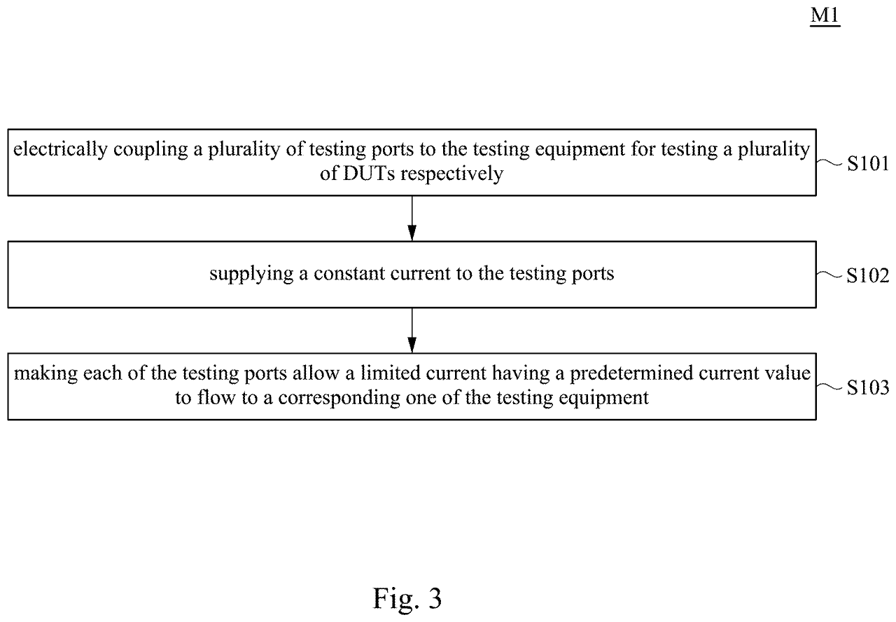

Reference is made to FIG. 3. FIG. 3 illustrates a flow chart of a method M1 for testing a plurality of DUTs 200 according to one embodiment of the present disclosure. As shown in FIG. 3, the method M1 includes: electrically coupling a plurality of testing ports 120 to the DUTs 200 respectively (S101); supplying a constant current to the testing ports 120 (S102); and making each of the testing ports 120 allow a limited current having a predetermined current value to flow to a corresponding one of the DUTs 200 (S103). In some embodiments, a sum of the limited currents respectively flowing through the testing ports 120 is equal to or smaller than the constant current, but the present disclosure is not limited by this. The total current supplied by the power supply 110 can be determined by the sum of the adjusted currents, and the total current can also be adjusted according to the requirements of the production line to maintain the maximum efficiency of the production line. In some embodiments, the method M1 further includes making electrical disconnection inside at least one of the testing ports 120 when at least one of the DUTs 200 corresponding thereto is determined to be failed. Specifically, the production line contains multiple DUTs 200 for simultaneous testing operations. When any DUT 200 that is determined to meet a shutdown conditions during the testing process, it will be closed after the testing process is completed.

According to the previous descriptions, in some embodiments, the testing ports 120 can have different electrical connections. For example, as in the embodiment shown in FIG. 1, the testing ports 120 are electrically connected to the power supply 110 in parallel. Then, the current flows from the power supply 110 and is transmitted to each of the testing ports 120. The current clampers 124 of the testing ports 120 can set a predetermined current value. When the current flows to each testing port 120, the current clampers 124 can limit the value of the input current flowing into the testing ports 120 according to the predetermined current value. For example, in some embodiments, each of the testing ports 120 may have a current clamper 124 that can set a predetermined current value, and the input current can be limited by the current clamper 124. The specific current limiting details of the current clamper 124 are described below.

In some embodiments, a sum of the limited currents respectively flowing through rest of the testing ports 120 is smaller than the constant current. Specifically, the disclosure provides a method for testing a plurality of DUTs by comparing the predetermined current value and the value of the input current to determine whether to allow the input current to pass, but the present disclosure is not limited to this. Other suitable current limiting methods can also be used. For example, one of the other suitable current limiting methods is allocating the input current of each DUT 200 according to a specific ratio. The setting of the predetermined current value can be adjusted according to the power supply 110. For example, when the value of the input current is equal to or greater than a predetermined current value, the input current can pass the current clamper 124. On the other hand, if the value of the input current is smaller than the predetermined current value, the testing port 120 will form an open circuit and no current flows through. In order to maintain the performance of the production line, the total current value provided by the power supply 110 must be set in the consideration of the predetermined current value of each current clamper 124. Therefore, in some embodiments, the constant current is greater than the sum of the limited currents respectively flowing through the rest of the testing ports 120, but the disclosure is not limited to this.

Specifically, the electrical disconnection can be achieved by remote controlling. The remote controlling may be achieved by combining the aforementioned switch 126 and current clamper 124 with a remote control system. When a problem is found in one of the DUTs 200, the remote control system can disconnect the electrical connection between the problematic DUT 200 and the power supply 110 to prevent the problematic DUT 200 from continuing to operate. For example, when in the test process, each DUT 200 can be independently tested to determine whether the test result thereof meets the shutdown conditions. When the shutdown conditions are met, the problematic DUT 200 will be disconnected from the power supply 110 through controlling the switch 126 by the remote control system, which can save testing time for the next testing item.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

1. A testing device, comprising:
a power supply; and
a plurality of testing ports electrically connected to the power supply, each of the testing ports comprising:
a contact configured to electrically couple a device under test (DUT); and
a current clamper connected between the power supply and the contact and configured to allow a limited current having a predetermined constant current value to flow to the contact.

2. The testing device of claim 1, wherein the testing ports are connected in parallel.

3. The testing device of claim 1, wherein the current clamper is configured to allow the limited current to flow to the contact when a current from the power supply to the current clamper is equal to or greater than the limited current.

4. The testing device of claim 1, wherein the current clamper is configured to not allow the limited current to flow to the contact when a current from the power supply to the current clamper is smaller than the limited current.

5. The testing device of claim 1, wherein said each of the testing ports further comprises a switch connected between the power supply and the current clamper.

6. The testing device of claim 1, wherein the power supply is configured to provide a constant current, and a sum of the limited currents respectively flowing through the current clampers is equal to or smaller than the constant current.

7. A method for testing a plurality of devices under test (DUTs), the method comprising:
electrically coupling a plurality of testing ports to the DUTs respectively;
supplying a constant current to the testing ports; and
making each of the testing ports to allow a limited current having a predetermined constant current value to flow to a corresponding one of the DUTs.

8. The method of claim 7, wherein a sum of the limited currents respectively flowing through the testing ports is equal to or smaller than the constant current.

9. The method of claim 7, further comprising:
making electrical disconnection inside at least one of the testing ports when at least one of the DUTs corresponding thereto is determined to be failed.

10. The method of claim 9, wherein a sum of the limited currents respectively flowing through rest of the testing ports is smaller than the constant current.
